(19) United States
(12) Patent Application Publication
(10) Pub. No.: US 2025/0357414 A1
(43) Pub. Date: Nov. 20, 2025

(54) SEMICONDUCTOR DEVICE AND METHOD OF MANUFACTURING THE SAME

(71) Applicants: Kabushiki Kaisha Toshiba, Tokyo (JP); Toshiba Electronic Devices & Storage Corporation, Tokyo (JP)

(72) Inventor: Kazuya MARUYAMA, Higashikurume Tokyo (JP)

(21) Appl. No.: 19/024,686

(22) Filed: Jan. 16, 2025

(30) Foreign Application Priority Data
May 20, 2024 (JP) P2024-081469

(51) Int. Cl. H01L 23/00

(52) U.S. Cl. CPC H01L 24/48; H01L 24/45; H01L 24/85; H01L 2224/45014; H01L 2224/48091; H01L 2224/4813; H01L 2224/48458; H01L 2224/48472; H01L 2224/852; H01L 2224/85947

(57) ABSTRACT

According to one embodiment, a semiconductor device includes: a substrate; a first electrode provided on the substrate; a second electrode provided on the substrate distant from the first electrode; and a sheet-like conductive sheet configured to connect the first electrode and the second electrode, in which the conductive sheet includes a first fixing portion connected to the first electrode, a second fixing portion connected to the second electrode, and a wiring portion positioned between the first fixing portion and the second fixing portion, having a length in a first direction from the substrate toward the first electrode that is longer than a length of the first fixing portion in the first direction, and having a convex shape with its central part is curving away from the second fixing portion at a first end that is connected to the first fixing portion.

### CROSS-REFERENCE TO RELATED APPLICATION

This application is based upon and claims the benefit of priority from Japanese Patent Application No. 2024-081469, filed May 20, 2024, the entire contents of which are incorporated herein by reference.

### FIELD

Embodiments described herein relate generally to a semiconductor device and a method of manufacturing the same.

### BACKGROUND

A semiconductor device where a wire is connected to an electrode by ball bonding is known. For a wire having a thick wire diameter, a method of connection by wedge bonding is known. In addition, a semiconductor device where a conductive sheet is connected by wedge bonding is known. Examples of related art include JP-A-2024-022890 and JP-B-7293142.

### DESCRIPTION OF THE DRAWINGS

FIG. 1 is a diagram illustrating an example of a circuit configuration of a semiconductor device according to a first embodiment.

FIG. 2 is a top view illustrating the semiconductor device according to the first embodiment.

FIG. 3 is a cross-sectional view taken along line A-A′ illustrated in FIG. 2.

FIG. 4 is an enlarged cross-sectional view illustrating a fixing portion between an electrode and a conductive sheet.

FIG. 5 is an enlarged top view illustrating the fixing portion between the electrode and the conductive sheet.

FIG. 6 is an enlarged top view illustrating the fixing portion between the electrode and the conductive sheet.

FIG. 7 is a cross-sectional view illustrating a semiconductor device according to a second embodiment.

FIG. 8 is an enlarged top view illustrating a fixing portion between an electrode and a conductive sheet of the semiconductor device according to the second embodiment.

FIG. 9A is a diagram illustrating a state where the conductive sheet is discharged from a capillary.

FIG. 9B is a diagram illustrating a step of lowering the capillary and connecting the conductive sheet to the electrode.

FIG. 9C is a diagram illustrating a step of lifting the capillary.

FIG. 9D is a diagram illustrating a step of forming a wiring portion.

FIG. 10 is a cross-sectional view illustrating a step of connection by the capillary.

FIG. 11A is a diagram illustrating the capillary after forming the wiring portion.

FIG. 11B is a diagram illustrating a step of lowering the capillary and connecting the conductive sheet to the electrode.

FIG. 11C is a diagram illustrating a step of lifting the capillary.

FIG. 11D is a diagram illustrating a step of moving the capillary.

FIG. 11E is a diagram illustrating a step of cutting off the conductive sheet.

### DETAILED DESCRIPTION

Embodiments provide a semiconductor device capable of reducing damage to a chip to improve reliability.

In general, according to one embodiment, a semiconductor device includes: a substrate; a first electrode provided on the substrate; a second electrode provided on the substrate distant from the first electrode; and a sheet-like conductive sheet configured to connect the first electrode and the second electrode, in which the conductive sheet includes a first fixing portion connected to the first electrode, a second fixing portion connected to the second electrode, and a wiring portion positioned between the first fixing portion and the second fixing portion, having a length in a first direction from the substrate toward the first electrode that is longer than a length of the first fixing portion in the first direction, and having a convex shape in a direction from the wiring portion toward the first fixing portion at a first end that is connected to the first fixing portion. For example, the convex shape with its central part is curving away from the second fixing portion at the first end.

A method of manufacturing a semiconductor device according to another embodiment includes: a step of moving a capillary where a hole having an arc-shaped portion is filled with a sheet-like conductive sheet toward a first electrode and connecting the conductive sheet and the first electrode to each other to form a first fixing portion; a step of moving the capillary toward a second electrode to form a wiring portion; a step of connecting the conductive sheet and the second electrode to each other to form a second fixing portion; and a step of cutting off the conductive sheet.

Hereinafter, each of embodiments of the present disclosure will be described with reference to the drawings.

The drawings are schematic or conceptual, in which a relationship between the thickness and the width of each component, a ratio between the sizes of components, and the like are not necessarily the same as the actual ones. In addition, when the same component is illustrated in different drawings, a dimension or a ratio of the component may vary depending on the drawings.

A direction from a source electrode 154s toward a fixing portion Js will be referred to as a Z direction (first direction). In addition, a direction orthogonal to the Z direction will be referred to as an X direction (second direction), and a direction intersecting with the X direction and the Z direction will be referred to as an Y direction (third direction). The X direction, the Y direction, and the Z direction have an orthogonal relationship in the present embodiment. However, the X direction, the Y direction, and the Z direction may have a relationship in which the directions intersect with each other without being limited to being orthogonal.

In addition, for convenience of description, a positive direction of the Z direction will be referred to as “upper”, and a negative direction of the Z direction will be referred to as “lower” relative to the origin of the coordinate axes. It should be noted that the “upper” and “lower” directions are not limited to the gravity direction or directions during mounting of a semiconductor device.

In the present specification and each of the drawings, the same elements as those described with reference to the previous drawings are represented by the same reference numerals, and the detailed description thereof will not be appropriately repeated.

### First Embodiment

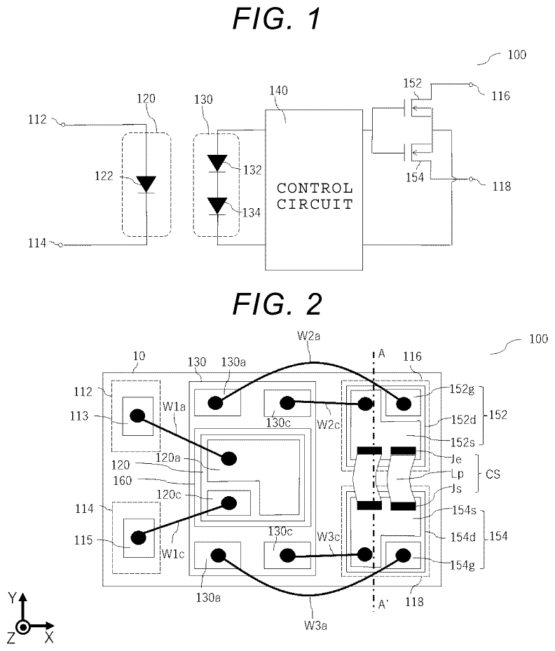

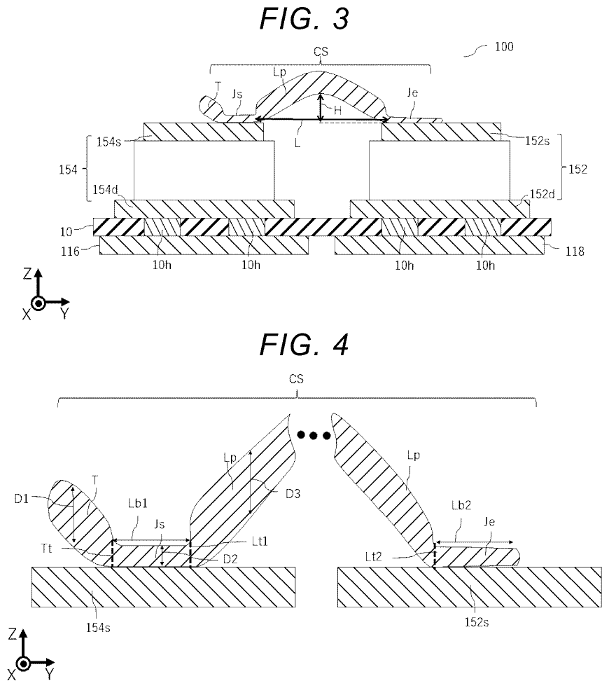

FIG. 1 illustrates an example of a circuit diagram of a semiconductor device 100 according to a first embodiment. FIG. 2 is a top view illustrating the semiconductor device 100 according to the first embodiment. FIG. 3 is a cross-sectional view taken along line A-A′ illustrated in FIG. 2.

The semiconductor device 100 illustrated in FIG. 1 is, for example, a photo relay that transmits an alternating current signal or a direct current signal. The semiconductor device 100 includes terminals 112, 114, 116, and 118. A voltage for driving the semiconductor device 100 is supplied to the terminals 112 and 114. While the semiconductor device 100 is driven, a signal is transmitted between the terminal 116 and the terminal 118.

The semiconductor device 100 includes a light emitting element 120, a light receiving element 130, a control circuit 140, and transistors 152 and 154.

The light emitting element 120 includes, for example, at least a diode 122 that is an LED (light emitting diode). An anode and a cathode are connected to the terminals 112 and 114, respectively. The diode 122 is driven with a voltage applied to the terminals 112 and 114 to emit light.

The light receiving element 130 includes, for example, diodes 132 and 134 that are PDAs (photo diode arrays). The diodes 132 and 134 receive light emitted from the diode 122 (the light receiving element 130 is optically coupled with the light emitting element 120). The light receiving element 130 may include a photo transistor. FIG. 1 illustrates an example where two diodes are provided in series as the light receiving element 130, but the number of diodes and a connection method are not limited thereto. The number of the diodes may be one or three or more, at least of which may be connected in parallel.

The control circuit 140 is connected to both ends of the light receiving element 130. The control circuit 140 controls gate potentials of the transistors 152 and 154 using an photovoltaic power of the light receiving element 130 such that the transistors 152 and 154 enter an ON state.

An example where the transistors 152 and 154 are MOSFETs will be described. Drain electrodes of the transistors 152 and 154 are connected to the terminals 116 and 118, respectively. Gate electrodes of the transistors 152 and 154 are connected to an anode of the light receiving element 130 through the control circuit 140. Source electrodes of the transistors 152 and 154 are connected to a cathode of the light receiving element 130 through the control circuit 140.

That is, a potential difference between the anode and the cathode of the light receiving element 130 is converted into a potential difference between the gate electrodes and the source electrodes of the transistors 152 and 154 through the control circuit 140.

Next, an operation of the semiconductor device 100 will be described.

Initially, when the potential difference between the terminals 112 and 114 is less than a predetermined value and the light emitting element 120 is in an OFF state, the gate potentials of the transistors 152 and 154 are lower than a threshold voltage. Therefore, there is no conduction between the sources and the drains, and a signal is not transmitted between the terminals 116 and 118.

Next, when a voltage is applied to the terminals 112 and 114 to turn on the light emitting element 120, the diode 122 of the light emitting element 120 emits light. The diodes 132 and 134 of the light receiving element 130 receives light from the diode 122. The light receiving element 130 generates a potential difference between the anode and the cathode due to an electromotive force, converts the generated potential difference into a gate potential of the transistors 152 and 154 through the control circuit 140, and turns on the transistors 152 and 154.

There is no conduction between the sources and the drains of the transistors 152 and 154, and a signal is transmitted between the terminals 116 and 118.

When the voltages of the terminals 112 and 114 are controlled such that the light emitting element 120 turns off, irradiation of the light receiving element 130 with the light from the light emitting element 120 is stopped. The transistors 152 and 154 turn off again, a signal is not transmitted between the terminals 116 and 118.

That is, the semiconductor device 100 controls the transmission of the signal between the terminals 116 and 118 according to the voltages applied to the terminals 112 and 114.

Next, a planar structure of the semiconductor device 100 according to the present embodiment will be described with reference to FIG. 2.

In addition to the elements illustrated in FIG. 1, the semiconductor device 100 includes a substrate 10, electrodes 113 and 115, an adhesive layer 160, wirings W1a, W1c, W2a, W2c, W3a, and W3c, and a conductive sheet CS.

The terminals 112, 114, 116, and 118 corresponding to regions surrounded by dotted lines in FIG. 2, respectively, are disposed on a lower surface of the substrate 10, for example. The electrode 113 is connected to the terminal 112 of the lower surface through a conductor (not illustrated). The electrode 115 is connected to the terminal 114 of the lower surface through a conductive region (not illustrated).

The light emitting element 120 includes an anode electrode 120a and a cathode electrode 120c. The light receiving element 130 includes an anode electrode 130a and a cathode electrode 130c. The transistor 152 includes a source electrode 152s, a drain electrode 152d, and a gate electrode 152g. The transistor 154 includes the source electrode 154s, a drain electrode 154d, and a gate electrode 154g.

The light receiving element 130 is provided on an upper surface of the substrate 10. The light emitting element 120 is provided on the upper surface of the light receiving element 130 with the adhesive layer 160 interposed therebetween. The light emitting element 120 and the light receiving element 130 are stacked. The anode electrode 120a and the cathode electrode 120c are provided on an upper surface of the light emitting element 120. The anode electrode 130a and the cathode electrode 130c are provided at a position distant from the light emitting element 120 on the upper surface of the light receiving element 130.

The light emitting element 120 is positioned between the anode electrode 130a and the cathode electrode 130c in the Y direction, for example. A plurality of the anode electrodes 130a and a plurality of the cathode electrodes 130c are provided, and the light emitting element 120 is positioned between the plurality of anode electrodes 130a in the Y direction, for example. By providing the plurality of anode electrodes 130a and the plurality of cathode electrodes 130c, the wiring length to the transistors 152 and 154 is reduced, and conduction loss is reduced, which is desirable.

The electrode 113 is connected to the anode electrode 120a through the wiring W1a. The electrode 115 is connected to the cathode electrode 120c through the wiring W1c. The light emitting element 120 is driven by an electrical signal input to the anode electrode 120a and the cathode electrode 120c. Light emitted from the light emitting element 120 reaches the light receiving element 130 facing the light emitting element 120 with the adhesive layer 160 interposed therebetween. The adhesive layer 160 is, for example, an insulating material that is permeable to light of a frequency emitted from the diode 122. The light emitting elements 120 and 130 are electrically insulated from each other and are optically coupled with each other.

The optical signal received by the light receiving element 130 is converted into an electromotive force between the anode electrode 130a and the cathode electrode 130c. FIG. 2 illustrates an example where two anode electrodes 130a and two cathode electrodes 130c are provided. The control circuit 140 illustrated in FIG. 1 is not illustrated in FIG. 2, and a potential difference between the anode electrode 130a and the cathode electrode 130c may be a value controlled by the control circuit 140. That is, the light receiving element 130 illustrated in FIG. 2 may include the control circuit 140.

Among the anode electrodes 130a, the anode electrode 130a that is positioned in the positive direction of the Y direction in FIG. 2 is connected to the gate electrode 152g through the wiring W2a, assuming the origin is located in the middle of the terminals 116 and 118. Among the anode electrodes 130a, the anode electrode 130a that is positioned in the negative direction of the Y direction in FIG. 2 is connected to the gate electrode 154g through the wiring W3a.

Among the cathode electrodes 130c, the cathode electrode 130c that is positioned in the positive direction of the Y direction in FIG. 2 is connected to the source electrode 152s through the wiring W2c. Among the cathode electrodes 130c, the cathode electrode 130c that is positioned in the negative direction of the Y direction in FIG. 2 is connected to the source electrode 154s through the wiring W3c.

The transistors 152 and 154 are positioned in the positive direction of the X direction further than the light emitting element 120 and the light receiving element 130. The transistors 152 and 154 are located side by side in the Y direction. The source electrodes 152s and 154s and the gate electrodes 152g and 154g are provided distant from each other on upper surfaces of the transistors 152 and 154. The drain electrodes 152d and 154d are provided on lower surfaces of the transistors 152 and 154.

The drain electrode 152d of the transistor 152 is connected to the terminal 116 of the lower surface through a conductive region not illustrated in FIG. 2. The drain electrode 154d of the transistor 154 is connected to the terminal 118 of the lower surface through a conductive region not illustrated in FIG. 2.

The electromotive force of the light receiving element 130 is converted into a potential difference between the gate electrodes 152g and 154g and the source electrodes 152s and 154s of the transistors 152 and 154. When the light receiving element 130 is irradiated with light such that the anode electrode 130a has a higher potential than the cathode electrode 130c, the potentials of the gate electrodes 152g and 154g of the transistors 152 and 154 exceed threshold voltages such that the transistors 152 and 154 turns on.

The source electrode 152s and the source electrode 154s are electrically connected through the conductive sheet CS. Here, the conductive sheet CS is, for example, a sheet-like conductor different from a wire. The sheet-like conductor is, for example, a conductor that may be in contact with an electrode in an area wider than an area where a wire having a circular cross-section and the electrode are in contact with each other. More specifically, the conductive sheet CS is, for example, a conductive ribbon. The conductive sheet CS includes, for example, at least one element such as Al, Cu, Ag, or Au.

The conductive sheet CS has, for example, a cross-section having a rectangular shape, an elliptical shape, an oval shape, an egg shape, or the like with a long side and a short side shorter than the long side in a plane perpendicular to an extending direction. Hereinafter, the length of the long side of the cross-section of the conductive sheet CS will also be simply referred to as the width.

While the transistors 152 and 154 are in ON state, an electrical signal is transmitted between the terminal 116 and the terminal 118 through the drain electrode 152d, the source electrode 152s, the conductive sheet CS, the source electrode 154s, and the drain electrode 154d.

The conductive sheet CS includes a fixing portion Je connected to the source electrode 152s and the fixing portion Js connected to the source electrode 154s. A wiring portion Lp is positioned between the fixing portion Je and the fixing portion Js. The wiring portion Lp is an intermediate portion positioned between the fixing portion Je and the fixing portion Js in the Y direction. The wiring portion Lp may include a portion positioned in the positive direction of the Z direction further than the fixing portions Je and Js, and has, for example, an arch shape. In addition, at least a part of the wiring portion Lp may be formed in a loop shape along an arc. FIG. 2 illustrates an example where two conductive sheets CS are located in the X direction, but the number of conductive sheets CS is not limited thereto. One conductive sheet CS may be provided, or three or more conductive sheets CS may be provided.

The source electrode 152s includes a first region to which the fixing portion Je of the conductive sheet CS is connected and a second region that has a shorter length in the X direction than the first region and to which the wiring W2c is connected. The gate electrode 152g is provided in the positive direction of the Y direction further than the first region, and is provided in the positive direction of the X direction further than the second region.

Likewise, the source electrode 154s includes a first region to which the fixing portion Js of the conductive sheet CS is connected and a second region that has a shorter length in the X direction than the first region and to which the wiring W3c is connected. The gate electrode 154g is provided in the negative direction of the Y direction further than the first region, and is provided in the positive direction of the X direction further than the second region.

The substrate 10 is, for example, a flexible printed circuit (FPC) including polyimide.

The wirings W1a, W1c, W2a, W2c, W3a, and W3c are, for example, wires formed by wire bonding. W1a, W1c, W2a, W2c, W3a, and W3c include, for example, at least any one of Al, Cu, Ag, or Au. The wirings W1a, W1c, W2a, W2c, W3a, and W3c and the respective electrodes are connected, for example, by ball bonding. Cross-sections of the wirings W1a, W1c, W2a, W2c, W3a, and W3c are, for example, circular.

The semiconductor device 100 may be sealed with a seal material (not illustrated).

Next, a cross-sectional view taken along line A-A′ illustrated in FIG. 2 will be described with reference to FIG. 3. FIG. 3 illustrates a plurality of conductive regions 10h through which the upper surface and the lower surface of the substrate 10 are connected.

The conductive region 10h extends in the Z direction in the substrate 10. FIG. 3 illustrates an example where two conductive regions 10h are provided in each of the terminals 116 and 118. The number of conductive regions may be one or three or more.

In addition, the connection of the terminals 112 and 114 and the electrodes 113 and 115 illustrated in FIG. 2 may also be made using the same structure.

The terminals 116 and 118 are provided on the lower surface of the substrate 10, and are connected to the drain electrodes 152d and 154d of the upper surface of the substrate 10 through the conductive regions 10h. The transistors 152 and 154 includes the source electrodes 152s and 154s on the upper surface, and includes the drain electrodes 152d and 154d on the lower surface.

The conductive sheet CS includes an end portion T not illustrated in FIG. 2. The end portion T is adjacent to, for example, at least one of the fixing portion Js and the fixing portion Je. The end portion T is adjacent to, for example, the fixing portion Js in the Y direction, and is positioned in a direction opposite to the wiring portion Lp with respect to the fixing portion Js. The end portion T is distant from the source electrode 154s in the Z direction.

The conductive sheet CS and the source electrode 152s are connected in the fixing portion Je. The fixing portion Je may or may not include the end portion T that is positioned in the direction opposite to the wiring portion Lp with respect to the fixing portion Je.

The wiring portion Lp of the conductive sheet CS has a height H in the Z direction and a length L in the X direction. Here, the length L is a distance between the fixing portion Je and the fixing portion Js. The length L satisfies, for example, L≤1 mm. The height H satisfies, for example, H≤0.2 mm.

FIG. 4 is an enlarged cross-sectional view illustrating the periphery of the fixing portions Js and Je. The details of the connection of the source electrodes 152s and 154s and the conductive sheet CS will be described.

The left side of FIG. 4 illustrates the end portion T, the wiring portion Lp, and the fixing portion Js that is connected to the source electrode 154s between the end portion T and the wiring portion Lp in the conductive sheet CS. In at least a part of the end portion T, a length D1 in the Z direction is longer than a length D2 of the fixing portion Js in the Z direction. In at least a part of the wiring portion Lp, a length D3 in the Z direction is longer than a length D2 of the fixing portion Je in the Z direction.

A first end Lt1 is positioned at an end of the wiring portion Lp on the side of the fixing portion Js (the negative direction of the Y direction), and a level difference is generated at the first end Lt1 due to a difference in the length of the conductive sheet CS in the Z direction. In other words, a position where the level difference is generated in the Z direction can be considered as the first end Lt1 of the wiring portion Lp (a boundary between the wiring portion Lp and the fixing portion Js). A second end Lt2 is positioned at an end of the wiring portion Lp on the side of the fixing portion Je (the positive direction of the Y direction), and a level difference is generated at the second end Lt2 due to a difference in the length of the conductive sheet CS in the Z direction. In other words, a position where the level difference is generated in the Z direction can be considered as the second end Lt2 of the wiring portion Lp (a boundary between the wiring portion Lp and the fixing portion Je). The first end Lt1 is an end of the wiring portion Lp in the negative direction of the Y direction, and the second end Lt2 is an end of the wiring portion Lp in the positive direction of the Y direction.

On the other hand, a third terminal (third end) Tt is positioned at an end of the end portion T on the side of the fixing portion Js (the positive direction of the Y direction), and a level difference is generated at the third terminal Tt due to a difference in the length of the conductive sheet CS in the Z direction. In other words, a position where the level difference is generated in the Z direction can be considered as the third terminal Tt of the end portion T (a boundary between the end portion T and the fixing portion Js). The third terminal Tt is an end of the end portion T in the positive direction of the Y direction. The first end Lt1, the second end Lt2, and the third terminal Tt described above may be defined as the position of the level differences in the Z direction, and may be defined as a boundary between a portion where the conductive sheet CS and the source electrode 154s are joined and a portion where the conductive sheet CS and the source electrode 154s are distant from each other.

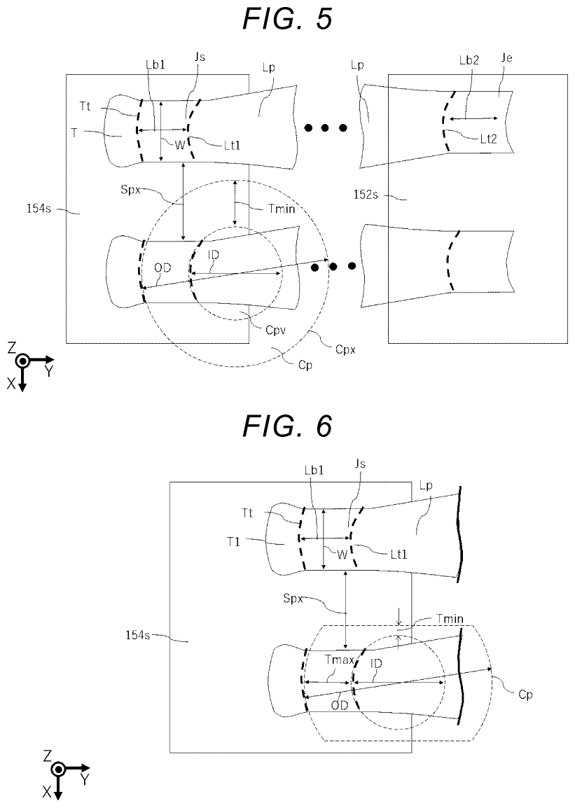

The fixing portion Js has a length Lbl in the Y direction from the third terminal Tt of the end portion T to the first end Lt1 of the wiring portion Lp. As described below with reference to FIG. 5, the length Lbl is defined at the center of the conductive sheet CS in the X direction.

As described below in a manufacturing step, the reason why the level difference is generated at the first end Lt1, the second end Lt2, and the third terminal Tt due to a difference in the length of the conductive sheet CS in the Z direction is that the conductive sheet CS and the source electrode 154s are connected by pressing the conductive sheet CS to the source electrode 154s and the length D2 of the fixing portion Js in the Z direction is shorter than the original length (for example, the length D3) of the conductive sheet CS in the Z direction.

The right side of FIG. 4 illustrates the wiring portion Lp, the fixing portion Je, and the source electrode 152s. A part of the wiring portion Lp of the conductive sheet CS is illustrated in the drawing. The length of the fixing portion Je in the Z direction may be, for example, uniform in the Y direction, and may gradually decrease toward the positive direction of the Y direction (direction from the wiring portion Lp toward the fixing portion Je). Depending on the shape of a tip Cpt of a capillary Cp described below, the shape of the fixing portion Je can be appropriately selected.

On the side of the fixing portion Je opposite to the wiring portion Lp, for example, the portion such as the end portion T that is continuous to the fixing portion Js does not need to be positioned. That is, the fixing portion Je is positioned at an end of the conductive sheet CS in the positive direction of the Y direction, for example, as illustrated in FIG. 4.

FIG. 5 is a diagram illustrating the fixing portions Js and Je illustrated in FIG. 4 when seen from the top. A part of the wiring portion Lp is illustrated in the drawing. The fixing portion Js has a width W in the X direction and has the length Lb1 in the Y direction. The fixing portion Je has a length Lb2 in the Y direction. FIG. 5 illustrates an example where at least two conductive sheets CS are provided adjacent to each other in the X direction. The adjacent conductive sheets CS are located in the X direction at an interval Spx. The interval Spx is, for example, the shortest distance between the fixing portions Js of the conductive sheets CS located in the X direction.

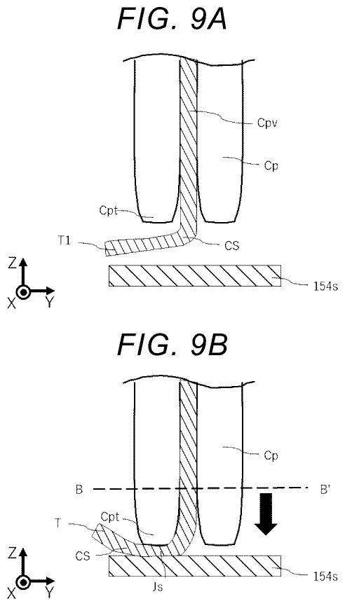

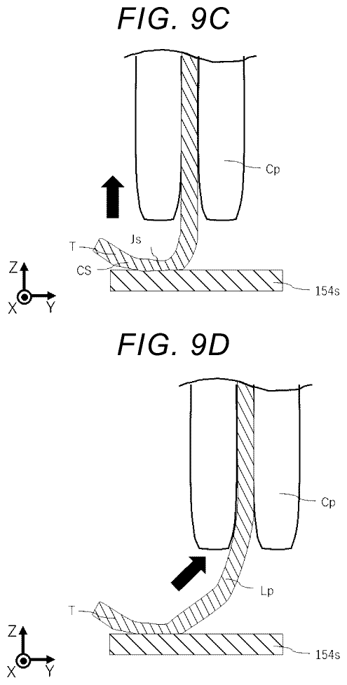

In FIG. 5, a cross-sectional shape of the capillary Cp that is an example of a tool for forming the fixing portion Js is illustrated as a region surrounded by a dotted line. The capillary Cp has a hole Cpv, and the vicinity of the tip of the capillary Cp (FIGS. 9A to 9D below) is formed in a cylindrical shape. A difference in radius between an external shape Cpx of the capillary Cp and the hole Cpv in an XY plane is called an inner thickness of the capillary Cp or simply a thickness. In general, the capillary Cp has a non-uniform inner thickness in an angular direction around the center of the hole Cpv in the XY plane. A minimum value of the inner thickness of the capillary Cp is called a minimum thickness Tmin. A maximum value of the inner thickness of the capillary Cp is called a maximum thickness Tmax.

It is desirable that the interval Spx satisfies Spx≥Tmin. When Spx≥Tmin is satisfied, interference between the capillary Cp and the conductive sheet CS adjacent thereto during bonding of the conductive sheet CS is reduced. The capillary Cp has an annular cross-section, for example, as illustrated in FIG. 5. That is, an inner diameter ID that is the diameter of the hole Cpv and an outer diameter OD that is the diameter of the external shape Cpx is, for example, fixed in the angular direction in the XY plane around the center of the hole Cpv. In this case, the capillary Cp has a uniform thickness, and each of the minimum thickness Tmin and the maximum thickness Tmax is equal to (OD−ID)/2.

When the fixing portion Js is formed, the conductive sheet CS and the source electrode 154s are connected with a length corresponding to the thickness of the capillary Cp. Accordingly, the length Lb1 of the fixing portion Js in the Y direction is ½ of the difference of the inner diameter ID and the outer diameter OD of the annular shape, which is equal to (OD−ID)/2. That is, in the capillary Cp having the annular cross-section, the minimum thickness Tmin and the length Lbl are equal to each other.

Accordingly, in the capillary Cp having the annular cross-section, it is desirable that the interval Spx satisfies Spx≥Lb1 from the viewpoint of reducing interference between the capillary Cp and the conductive sheet CS adjacent thereto during bonding of the conductive sheet CS is reduced.

On the other hand, the interval Spx and the length Lb1 do not need to satisfy Spx≥Lb1. For example, according to the cross-sectional shape of the capillary Cp illustrated in FIG. 6, in a shape where a part of the annular shape is linearly cut, the minimum thickness Tmin and the length Lb1 are different. For example, in the XY plane, the length of the outer diameter OD in the X direction is shorter than the length of the outer diameter OD in the Y direction.

In the example illustrated in FIG. 6, the minimum thickness Tmin that is (OD−ID)/2 in the X direction is less than the maximum thickness Tmax that is (OD−ID)/2 in the Y direction. The minimum thickness Tmin may be, for example, Tmax/2 or may be Tmax/3. In addition, the minimum thickness Tmin may be, for example, Tmax/4 or may be Tmax/5. In addition, the length Lb1 of the fixing portion Js in the Y direction is equal to, for example, the maximum thickness Tmax. Accordingly, the minimum thickness Tmin may be, for example, Lb1/2 or may be Lb1/3. In addition, the minimum thickness Tmin may be, for example, Lb1/4 or may be Lb1/5.

Accordingly, in the example illustrated in FIG. 6, the length Lb1 of the interval Spx satisfies, for example, Spx≥Tmin=Lb1/5 such that interference between the capillary Cp and the conductive sheet CS adjacent thereto during bonding of the conductive sheet CS is reduced. In other words, the interval Spx can be reduced, for example, in a range not falling below Lb1/5.

Referring back to FIG. 5, the first end Ltl and the second end Lt2 of the wiring portion Lp of the conductive sheet CS is formed in an arc shape. Here, the arc shape is, for example, a shape along a circular arc, and at least a part thereof may be along an arc or may be along an elliptical arc.

The first end Lt1 (the end of the wiring portion Lp in the negative direction of the Y direction) has, for example, a convex shape in the negative direction of the Y direction (direction from the wiring portion Lp toward the fixing portion Js). An end of one region having a convex shape represents that the end has a portion protruding from the inner side toward the outer side of the region. For example, an end of one region in the negative direction of the Y direction having a convex shape in the negative direction of the Y direction represents that, when one end and another end of the end of the region are connected with a straight line, at least a part of the end of the region is positioned in the negative direction of the Y direction further than the straight line.

The second end Lt2 of the wiring portion Lp (the end of the wiring portion Lp in the positive direction of the Y direction) has, for example, a concave shape in the negative direction of the Y direction (direction from the fixing portion Je toward the wiring portion Lp). An end of one region having a concave shape represents that the end has a portion that is recessed from the outer side toward the inner side of the region. An end of one region in the positive direction of the Y direction having a concave shape in the negative direction of the Y direction represents that, when one end and another end of the end of the region are connected with a straight line, at least a part of the end of the region is positioned in the negative direction of the Y direction further than the straight line.

The third terminal Tt of the end portion T has, for example, a concave shape in the negative direction of the Y direction (direction from the fixing portion Js toward the end portion T).

In addition, the shape of the first end Lt1, the second end Lt2, and the third terminal Tt can be restated as follows. The first end Lt1 of the wiring portion Lp has an arc shape, and the center of curvature of the first end Lt1 is positioned on the side of the wiring portion Lp with respect to the first end Lt1. Here, the center of curvature is the center of a circle that is disposed such that the circumference overlaps the arc-shaped first end Lt1. Likewise, the second end Lt2 of the wiring portion Lp has an arc shape, and the center of curvature of the second end Lt2 is positioned on the fixing portion Je side with respect to the second end Lt2. The third terminal Tt of the end portion T has an arc shape, and the center of curvature of the third terminal Tt is positioned on the side of the end portion T with respect to the third terminal Tt. A manufacturing method for determining the shape of the first end Lt1, the second end Lt2, and the third terminal Tt will be described below with respect to FIG. 9.

An interval in the X direction between the fixing portions Je of the plurality of conductive sheets CS that are provided is equal to, for example, the interval Spx. That is, the conductive sheet CS extends in a direction (for example, the Y direction) orthogonal to the X direction. It is desirable that the length Lb2 of the fixing portion Je in the Y direction and the interval Spx satisfy Spx≥Lb2. At least Spx≥Lb2/5 may be satisfied. The length Lb2 of the fixing portion Je in the Y direction is equal to, for example, the length Lb1 of the first fixing portion in the Y direction.

In the semiconductor device 100 according to the present embodiment, connection to a narrower region is possible by the plurality of conductive sheets CS and the reliability of the semiconductor device can be improved.

By locating side by side and forming the plurality of conductive sheets CS, a force (unit: N) required for bonding per conductive sheet CS is further reduced as compared to a case where bonding is executed using a first conductive sheet CS1 having a wider width. The reason for this is that, as the width of the conductive sheet CS increases and the contact area between the conductive sheet CS and the electrode increases, bonding needs to be executed strongly with a higher force (N) required for electrical connection. Even if a pressure (unit: Pa, force (N) per unit area required for bonding the conductive sheet CS is fixed, as the contact area between the conductive sheet CS and the electrode increases, a force (N) applied to a chip below the conductive sheet CS increases. Specifically, a concern of disconnection of an internal wiring of a chip where the transistor 152 or 154 is provided (for example, a gate wiring that is connected to the gate electrode 152g or 154g and is provided below the source electrode 152s or 154s) can be reduced. Accordingly, by providing the plurality of conductive sheets CS, damage to a chip during bonding can be reduced, and the reliability of the semiconductor device can be improved.

The connectability to a narrower region will be described. The interval Spx in the X direction between the plurality of conductive sheets CS that are provided can be reduced, for example, in a range not falling below Lb1/5. Here, the range of values that can be achieved as the interval Spx is determined depending on the shape of the capillary Cp. As illustrated in FIG. 6, when the thickness of the capillary Cp has the minimum thickness Tmin and the maximum thickness Tmax, the range of values that can be achieved as the interval Spx can be widened as compared to a case where the thickness of the capillary Cp is fixed. Even at the smaller interval Spx, bonding can be executed with reduced interference between the capillary Cp and the conductive sheet CS adjacent thereto. That is, in the semiconductor device according to the present embodiment, the range of the values of the interval Spx can be controlled by selecting the size of the capillary Cp, and the plurality of conductive sheets CS can be provided even in a narrower region by reducing the interval Spx.

As a result, the plurality of conductive sheets CS can be provided even in a narrower electrode, and by reducing a force applied to an electrode or a chip during the bonding of the conductive sheets CS, damage to the chip can be reduced such that the reliability of the semiconductor device can be improved.

Further, in the semiconductor device according to the present embodiment, the source electrodes 152s and 154s are connected through the conductive sheets CS such that the area connected to the electrodes can be increased as compared to a case where the connection is made by a wire. By increasing the area of the connection, electrical resistance can be reduced, and loss of signal transmission can be reduced.

In addition, by selecting the size of the capillary Cp, the interval Spx in the X direction between the conductive sheets CS can be reduced. By locating the conductive sheets CS more densely in the X direction, electrical resistance between the source electrode 152s and the source electrode 154s can be reduced such that the efficiency of signal transmission can be improved. By providing the plurality of conductive sheets CS on an electrode having a predetermined size at the narrower interval Spx, the contact area between the conductive sheet CS and the electrode can be increased to reduce electrical resistance.

In addition, the fixing portions Je and Js are formed by connecting the conductive sheets CS to the source electrodes 152s and 154s using the tip Cpt of the capillary Cp. The shape of the fixing portions Je and Js is determined depending on the shape of the capillary Cp. In particular, the third terminal Tt and the first end Lt1 can be controlled by selecting the shape of the capillary Cp.

### Second Embodiment

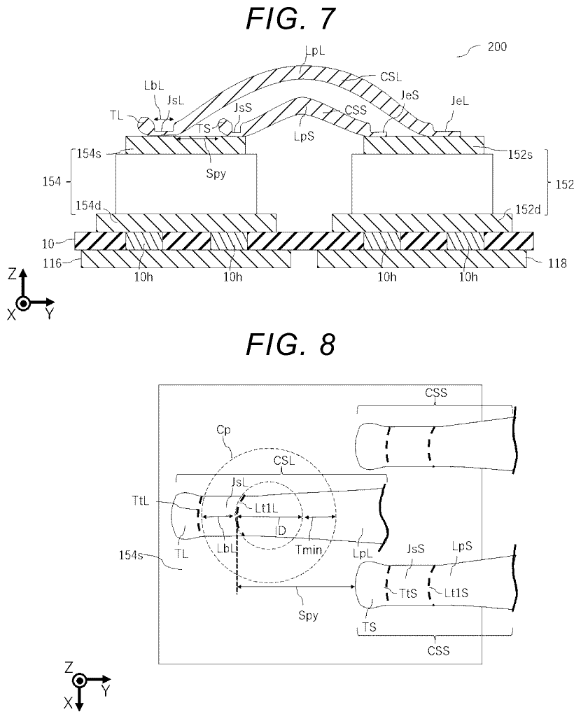

FIG. 7 is a cross-sectional view illustrating a semiconductor device 200 according to a second embodiment. FIG. 8 is an enlarged top view illustrating a fixing portion between a first conductive sheet CSS and a second conductive sheet CSL of FIG. 7 and the source electrode 154s. The description of portions common to those of the semiconductor device 100 according to the first embodiment will not be repeated. First, the description will be made with reference to FIG. 7.

As illustrated in FIG. 7, the semiconductor device 200 includes the first conductive sheet CSS and the second conductive sheet CSL. Both of the first conductive sheet CSS and the second conductive sheet CSL connect the source electrode 152s and the source electrode 154s to each other. A length of the first conductive sheet CSS in the Y direction is less than, for example, a length of the second conductive sheet CSL in the Y direction. In addition, at least a part of a wiring portion LpL of the second conductive sheet CSL is positioned, for example, above the first conductive sheet CSS.

A plurality of the first conductive sheets CSS and a plurality of the second conductive sheets CSL may be located side by side in the X direction.

The first conductive sheet CSS includes a fixing portion JsS that is connected to the source electrode 152s and an end portion TS that is distant from the source electrode 152s in the Z direction. The second conductive sheet CSL includes a fixing portion JsL that is connected to the source electrode 152s and an end portion TL that is distant from the source electrode 152s in the Z direction.

The fixing portion JsS of the first conductive sheet CSS and the fixing portion JsL of the second conductive sheet CSL are provided distant from each other in the Y direction. For example, the fixing portion JsL is positioned in the negative direction of the Y direction further than the fixing portion JsS. The fixing portion JsL is provided more distant from the source electrode 152s than the fixing portion JsS. The end portion TS is positioned between the fixing portion JsS and the fixing portion JsL in the Y direction. The end portion TL is positioned in the negative direction of the Y direction further than the fixing portion JsL.

In addition, on the source electrode 152s, a fixing portion JeS of the first conductive sheet CSS is positioned in the negative direction of the Y direction further than, for example, a fixing portion JeL of the second conductive sheet CSL. However, the first conductive sheet CSS does not need to be formed shorter than the second conductive sheet CSL, and the fixing portion JeS may be positioned in the positive direction of the Y direction further than the fixing portion JeL. The first conductive sheet CSS and the second conductive sheet CSL may be formed, for example, with the same length in the Y direction.

Next, the top view will be described with reference to FIG. 8. FIG. 8 illustrates an example where at least two first conductive sheets CSS are located side by side in the X direction. In addition, for example, one second conductive sheet CSL is illustrated. As illustrated in FIG. 8, the first conductive sheets CSS and the second conductive sheet CSL are disposed, for example, to be shifted from each other in the X direction. As in the cross-sectional view of FIG. 7, the first conductive sheet CSS and the second conductive sheet CSL at least partially overlap each other in the X direction.

FIG. 8 illustrates a cross-sectional shape of the capillary Cp as a region surrounded by a dotted line. A cross-section taken along an XY plane of the capillary Cp has, for example, an annular shape having an inner diameter ID. The thickness of the capillary Cp is, for example, uniform and has the minimum thickness Tmin.

A wiring portion LpS of the first conductive sheet CSS includes a first end Lt1S on the side of the fixing portion JsS (the negative direction of the Y direction). The end portion TS of the first conductive sheet CSS includes a third terminal TtS on the side of the fixing portion JsS (the positive direction of the Y direction). The wiring portion LpL of the second conductive sheet CSL includes a first end Lt1L on the side of the fixing portion JsL (the negative direction of the Y direction). The end portion TL of the second conductive sheet CSL includes a third terminal TtL on the side of the fixing portion JsL (the positive direction of the Y direction).

A length LbL of the fixing portion JsL in the Y direction and the minimum thickness Tmin of the capillary

Cp are, for example, equal to each other. In the wiring portion Lp, the first end Lt1L on the side of the fixing portion JsL has, for example, an arc shape and has a convex shape in the negative direction of the Y direction (direction from the wiring portion LpL toward the fixing portion JsL). The curvature radius of the first end Lt1L is determined, for example, depending on the shape and the inner diameter ID of the hole Cpv of the capillary Cp. The curvature radius of the first end Lt1L is, for example, ID/2. Conversely, the inner diameter ID can be calculated backward to be, for example, two times the curvature radius of the first end Lt1L.

An interval Spy is a distance in the Y direction between the end portion TS of the first conductive sheet CSS and the fixing portion JsL of the second conductive sheet CSL. When the first conductive sheet CSS does not include the end portion TS on the source electrode 154s, the interval Spy is a distance between the fixing portion JsS and the fixing portion JsL.

In order to reduce interference between the capillary Cp and the first conductive sheet CSS during formation of the fixing portion JsL, it is desirable that the interval Spy in the Y direction between the first conductive sheet CSS and the second conductive sheet CSL satisfies, for example, Spy≥Tmin+ID. If Tmin=LbL, it is desirable that Spy≥LbL+ID is satisfied.

A step of bonding the first conductive sheet CSS and the second conductive sheet CSL can start, for example, on one side from the source electrode 152s and on the other side from the source electrode 154s. Accordingly, the end portion TS and the end portion TL do not need to be positioned on the same electrode. FIG. 8 illustrates an example where bonding starts from the source electrode 154s for both of the first conductive sheet CSS and the second conductive sheet CSL. However, a bonding method is not limited to this example.

In the semiconductor device 200 according to the present embodiment, by locating the plurality of conductive sheets including the first conductive sheet CSS and the second conductive sheet CSL in the Y direction, connection to a narrower electrode through the plurality of conductive sheets CS can be made such that the reliability of the semiconductor device can be improved.

By providing the plurality of first conductive sheets CSS in the X direction and providing the second conductive sheet CSL in the Y direction, a bonding load required for joining the conductive sheet CS and the electrode can be reduced. The contact area of each of the conductive sheets with the electrode is reduced, and a pressing force required for junction is reduced. Damage to a chip can be reduced such that the reliability of the semiconductor device can be improved.

For example, by satisfying Spy≥LbL+ID for a narrow electrode, interference between the first conductive sheet CSS and the capillary Cp when the fixing portion JsL is formed using the capillary Cp is reduced. By selecting the shape of the capillary Cp (the minimum thickness Tmin or the inner diameter ID), the range of values that can be achieved as the interval Spy can be controlled. By reducing the interval Spy, even when the dimension of the source electrode 154s in the Y direction is smaller, the second conductive sheet CSL can be provided distant from the first conductive sheet CSS in the Y direction. By also providing the plurality of conductive sheets CS in the Y direction, electrical resistance between the source electrodes 152s and 154s can be reduced.

By reducing the interval Spy, the first conductive sheet CSS and the second conductive sheet CSL can be densely disposed on the source electrode 154s such that electrical resistance can be further reduced.

In addition, the first conductive sheet CSS and the second conductive sheet CSL can be shifted from each other in the X direction. By providing the second conductive sheet CSL at corresponding positions between the plurality of first conductive sheets CSS that are located in the X direction, interference between the capillary Cp and the first conductive sheet CSS during bonding of the fixing portion JsL can be further reduced. The reason for this is that the center of the capillary Cp during the bonding of the fixing portion JsL is positioned between the end portions TS of the first conductive sheets CSS in the X direction. By providing the first conductive sheet CSS and the second conductive sheet CSL to be shifted from each other in the X direction, Spy≥LbL+ID does not need to be satisfied. Even if Spy<LbL+ID, interference between the capillary Cp and the first conductive sheet CSS can be reduced.

In the semiconductor device according to at least one of the above-described embodiments, connection to a narrower region can be made by the plurality of conductive sheets CS and a force applied during bonding can be reduced such that damage to a chip can be reduced.

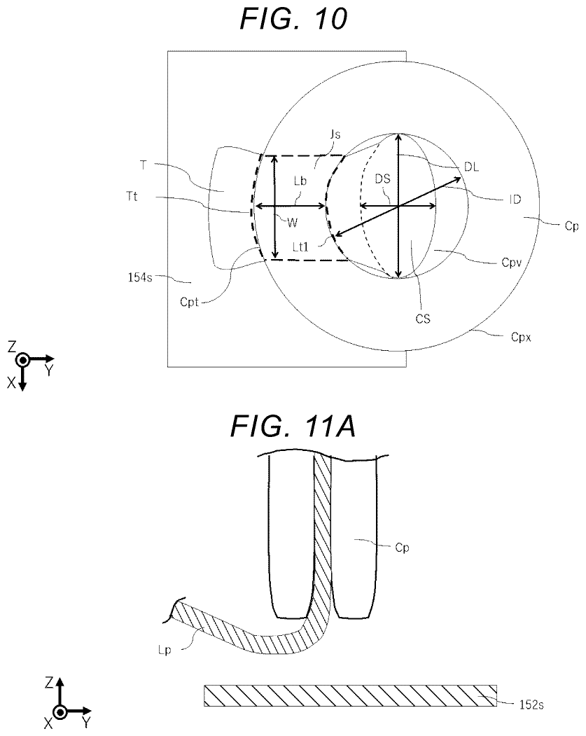

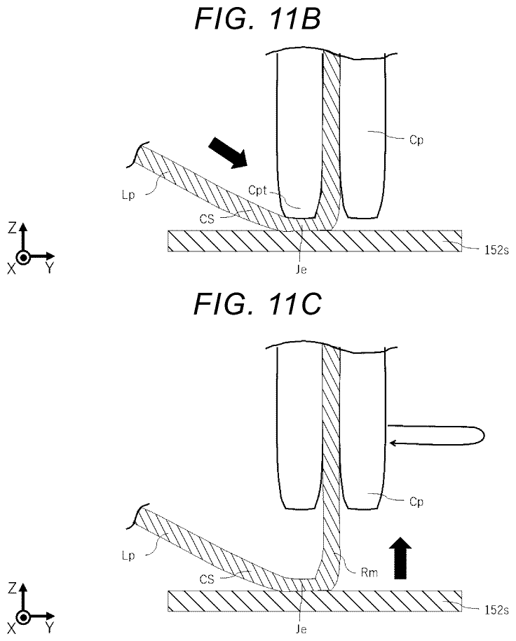

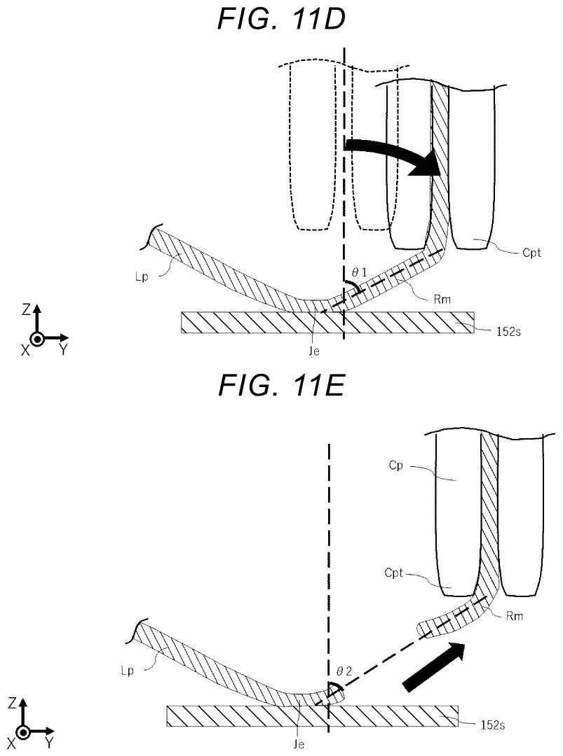

Next, a step of bonding the conductive sheet CS will be described with reference to FIGS. 9, 10, and 11. FIG. 9 illustrates a step of joining the conductive sheet CS to the electrode to start the formation of the wiring portion Lp. FIG. 10 is a cross-sectional view taken along line B-B′ illustrated in FIG. 9B. FIG. 11 illustrates a step of joining the conductive sheet CS to the electrode again and cutting off the conductive sheet CS after the formation of the wiring portion Lp.

First, a structure of the capillary Cp filled with the conductive sheet CS will be described. The capillary Cp includes the hole Cpv and the tip Cpt. The hole Cpv is filled with the conductive sheet CS. The conductive sheet CS is discharged through the hole Cpv. The tip Cpt is a portion closest to the electrode in the capillary Cp. The capillary Cp presses the conductive sheet CS at the tip Cpt such that the conductive sheet CS and the source electrode 154s are connected. For example, when the tip Cpt has a surface parallel to the upper surface of the source electrode 154s, the thickness of the fixing portion Js can be made uniform.

The capillary Cp may be, for example, a capillary used for ball bonding. The hole Cpv has, for example, a circular cross-section in the XY plane, and the shape of the hole Cpv is not limited to a circular shape.

FIG. 9A illustrates a state where the conductive sheet CS is discharged from the capillary Cp. Here, the conductive sheet CS is discharged from the hole Cpv by a sufficient length until the next step. The tip portion of the discharged conductive sheet CS corresponds to the end portion T.

Next, as illustrated in FIG. 9B, the capillary Cp is lowered in a direction of an arrow. The conductive sheet CS is interposed between the tip Cpt and the source electrode 154s. By pressing the capillary Cp in the direction of the arrow, the conductive sheet CS and the source electrode 154s are connected. In the step illustrated in FIG. 9B, ultrasonic vibration is applied from the capillary Cp to the fixing portion Js and the source electrode 154s. Heat may be applied to the source electrode 154s for more strong junction. By applying heat to the source electrode 154s, the connection between the fixing portion Je and the source electrode 154s is further enhanced. The end portion T is not compressed by the tip Cpt. The end portion T protrudes such that the conductive sheet CS and the source electrode 154s are connected widely over the entire surface of the tip Cpt.

Next, the capillary is lifted in a direction of an arrow illustrated in FIG. 9C. In the step of FIG. 9B, the fixing portion Js is formed in the conductive sheet CS, and the conductive sheet CS is connected to the source electrode 154s. As the capillary Cp is lifted, the conductive sheet CS is further discharged from the hole Cpv.

Next, by moving the capillary in a direction of an arrow illustrated in FIG. 9D, the formation of the wiring portion Lp starts.

Hereinabove, the steps until the starts of the formation of the wiring portion Lp are described.

FIG. 10 is a cross-sectional view taken along line B-B′ illustrated in FIG. 9B. The cross-section of the capillary Cp is, for example, annular. The external shape Cpx and the hole Cpv of the capillary have an arc-shaped portion. FIG. 10 illustrates an example where the capillary Cp has the circular external shape Cpx and the circular hole Cpv. The conductive sheet CS is connected to the source electrode 154s by the capillary Cp, and the fixing portion Js is formed. The fixing portion Js corresponds to a region surrounded by a dashed line.

The hole Cpv of the capillary Cp is filled with the conductive sheet CS, but the shape of the hole Cpv does not need to match with the shape of the conductive sheet CS. For example, FIG. 10 illustrates an example where, when the capillary Cp includes the circular hole Cpv, the hole Cpv is filled with the conductive sheet CS where a cross-section has an elliptical shape (a rectangular shape, an oval shape, or an egg shape). The hole Cpv may include a gap that is a portion not filled with the conductive sheet CS.

The conductive sheet CS includes a long side having a length DL and a short side having a length DS. The length DL is, for example, substantially equal to the inner diameter ID. The length DS is less than the inner diameter

ID. FIG. 10 does not necessarily illustrate the correct length relationships, and the width W of the fixing portion Js is substantially equal to the length DL. The width W of the fixing portion Js is spread by being pressed by the capillary Cp, and is more than the length DL. The shape of the hole Cpv of the capillary Cp may change depending on the shape of the conductive sheet CS.

In the example illustrated in FIG. 10, both of the third terminal Tt and the first end Lt1 have a shape along an arc. The third terminal Tt is determined depending on the shape of the external shape Cpx of the capillary Cp, and the first end Lt1 is determined depending on the shape of the hole Cpv. The hole Cpv and the external shape Cpx of the capillary Cp do not need to have a similar shape. For example, the capillary Cp having the shape illustrated in FIG. 6 may be used.

Next, the step of cutting off the conductive sheet CS after the formation of the wiring portion will be described with reference to FIG. 11.

First, FIG. 11A illustrates a state where the capillary Cp is moved toward the source electrode 152s after the formation of the wiring portion Lp.

FIG. 11B illustrates a state where the fixing portion Je is formed by lowering the capillary Cp such that the tip Cpt of the capillary Cp connects the conductive sheet CS and the source electrode 152s to each other. In the step illustrated in FIG. 11B, ultrasonic vibration is applied from the capillary Cp to the fixing portion Je and the source electrode 152s. Heat may be applied to the source electrode 152s for more strong connection. By applying heat to the source electrode 152s, the connection between the fixing portion Je and the source electrode 152s is further enhanced.

Next, as illustrated in FIG. 11C, the capillary Cp is lifted, and the conductive sheet CS is discharged. By lifting the capillary Cp, a residual portion Rm continuous to the fixing portion Je of the conductive sheet CS is discharged.

The step of FIG. 11C may further include a step of reciprocating the capillary Cp in a direction parallel to the upper surface of the source electrode 152s as shown by an arrow. Stress is applied to a boundary between the fixing portion Je and the residual portion Rm due to the reciprocation of the capillary Cp, and the cut-off is facilitated at the boundary between the fixing portion Je and the residual portion Rm in the subsequent cut-off step.

Next, as illustrated in FIG. 11D, the capillary Cp is moved, for example, along an arc around the fixing portion Je. An angle between a direction perpendicular to the source electrode 152s and a direction from the fixing portion Je toward the tip Cpt will be referred to as an angle θ1. Here, the angle θ1 is, for example, 45 degrees or more and less than 90 degrees. The angle θ1 may be desirably 60 degrees or more and less than 90 degrees. By moving the capillary Cp along the arc around the fixing portion Je, the distance between the fixing portion Je and the capillary Cp is maintained to be fixed, for example, in this step. That is, the residual portion Rm does not need to be further discharged from the capillary Cp. The capillary Cp does not need to move along the arc, and only needs to move at least in a direction intersecting the Z direction. However, it is desirable that the capillary Cp moves along the arc for the following reason. For example, when the capillary Cp is translated along the XY plane such that the distance between the fixing portion Je and the capillary Cp increases, a force is applied in a direction in which the conductive sheet CS is pulled. As compared to this case, by moving the capillary Cp along the arc, stress applied to the conductive sheet CS (for example, the fixing portion Je) can be reduced. By reducing the stress applied to the conductive sheet CS, a concern of cut-off of the conductive sheet CS can be reduced. In addition, by pulling the conductive sheet, a concern of separation of the conductive sheet CS from the capillary Cp can be reduced.

Finally, as illustrated in FIG. 11E, the capillary Cp is moved in a direction of an angle θ2 with respect to the direction perpendicular to the source electrode 152s. The conductive sheet CS is cut off at the boundary between the fixing portion Je and the residual portion Rm. The angle θ2 is, for example, 45 degrees or more and less than 90 degrees. The angle θ2 may be desirably 60 degrees or more and less than 90 degrees. The angles θ1 and θ2 are, for example, equal to each other but do not need to be equal to each other. The fixing portion Je and the residual portion Rm are cut off, and the residual portion Rm is used as the end portion T illustrated in FIG. 9A in the following connection step.

Next, a manufacturing step of providing the plurality of conductive sheets CS by repeating the bonding steps of FIGS. 9A to 9D and 11A to 11E will be described. A step of forming two conductive sheets CS (the first conductive sheet CS1 and a second conductive sheet CS2 that is provided after the first conductive sheet CS1) will be described using two examples. First, a case where the plurality of conductive sheets CS are located in the X direction as illustrated in FIG. 5 will be described.

First, in the steps illustrated in FIGS. 9A to 9D and 11A to 11E, bonding from the source electrode 154s to the source electrode 152s by the first conductive sheet CS1 is executed. The fixing portion Js of the first conductive sheet CS1 connected to the source electrode 154s will be referred to as a first fixing portion. The fixing portion Je of the first conductive sheet CS1 connected to the source electrode 152s will be referred to as a second fixing portion.

The manufacturing step of providing the plurality of conductive sheets CS further includes a step of moving the capillary Cp after cutting off the conductive sheet to form the first conductive sheet CS1 on the source electrode 152s as illustrated in FIG. 11E. Hereinafter, the fixing portion Js of the second conductive sheet CS2 connected to the source electrode 154s will be referred to as a third fixing portion. The fixing portion Je of the second conductive sheet CS2 connected to the source electrode 152s will be referred to as a fourth fixing portion.

The capillary Cp is moved, for example, to a region above the source electrode 154s after cutting off the conductive sheet to form the first conductive sheet CS1 on the source electrode 152s. In the region above the source electrode 154s, the capillary Cp is positioned distant from the first conductive sheet CS1 in the X direction. The capillary Cp is lowered toward the source electrode 154s to form the third fixing portion. The first fixing portion and the third fixing portion are distant from each other at a distance that is more than or equal to at least the minimum thickness Tmin of the capillary Cp (in the example of FIG. 5, Spx≥Tmin).

Next, in the steps illustrated in FIGS. 9A to 9D and 11A to 11E, the fourth fixing portion of the second conductive sheet CS2 is formed on the source electrode 152s, and the source electrode 154s and the source electrode 152s are electrically connected through the second conductive sheet CS2. Here, in the bonding steps, the first fixing portion of the first conductive sheet CS1 and the third fixing portion of the second conductive sheet CS2 (also, the second fixing portion of the first conductive sheet CS1 and the fourth fixing portion of the second conductive sheet CS2) are distant from each other in the X direction, and interference between the capillary Cp and the first conductive sheet CS1 during the formation of the second conductive sheet CS2 is reduced. Hereinabove, the example where the first conductive sheet CS1 and the second conductive sheet CS2 are provided distant from each other in the X direction is described.

Next, a case where the first conductive sheet CS1 and the second conductive sheet CS2 are provided distant from each other in the Y direction as in the first conductive sheet CSS and the second conductive sheet CSL illustrated in FIG. 8 will be described. That is, the example where the first conductive sheet CS1 is the first conductive sheet CSS of FIG. 8 and the second conductive sheet CS2 is the second conductive sheet CSL of FIG. 8 will be described.

First, in the steps illustrated in FIGS. 9A to 9D and 11A to 11E, bonding from the source electrode 154s to the source electrode 152s by the first first conductive sheet CS1 is executed. As illustrated in FIG. 11E, the manufacturing step further includes a step of moving the capillary Cp after cutting off the conductive sheet to form the first conductive sheet CS1 on the source electrode 152s as illustrated in FIG. 11E.

The capillary Cp is moved, for example, to a region above the source electrode 154s. In the region above the source electrode 154s, the capillary Cp is positioned distant from the first conductive sheet CS1 in the Y direction. The capillary Cp is lowered toward the source electrode 154s to form the third fixing portion. The first fixing portion and the third fixing portion are distant from each other at a distance that is more than or equal to at least a length obtained by adding the minimum thickness Tmin of the capillary Cp and the inner diameter ID of the capillary Cp (in the example of FIG. 8, Spx≥Tmin+ID).

First, in the steps illustrated in FIGS. 9A to 9D and 11A to 11E, bonding is executed again to form the second conductive sheet CS2 from the source electrode 154s to the source electrode 152s. Here, in the bonding steps, the first fixing portion of the first conductive sheet CS1 and the third fixing portion of the second conductive sheet CS2 (also, the second fixing portion of the first conductive sheet CS1 and the fourth fixing portion of the second conductive sheet CS2) are distant from each other in the Y direction, and interference between the capillary Cp and the first conductive sheet CS1 during the formation of the second conductive sheet CS2 is reduced.

In the description of the above-described example, the capillary Cp is positioned in the region above the source electrode 154s at the start of bonding of the second conductive sheet CS2. However, the bonding of the second conductive sheet CS2 may be executed from the source electrode 152s to the source electrode 154s. That is, the third fixing portion may be formed after forming the fourth fixing portion. Even in this case, the first fixing portion and the third fixing portion (also, the second fixing portion and the fourth fixing portion) are distant from each other in the X direction or the Y direction, and interference between the capillary Cp and the first conductive sheet CS1 during the formation of the second conductive sheet CS2 is reduced.

In the above-described step of forming the plurality of conductive sheets CS including the first conductive sheet CS1 and the second conductive sheet CS2, the first conductive sheet CS1 and the second conductive sheet CS2 are distant from each other in the X direction or the Y direction, and interference between the capillary Cp and the first conductive sheet CS1 is reduced. By appropriately selecting the shape and dimension of the capillary Cp, the interval between the first conductive sheet CS1 and the second conductive sheet CS2 can be controlled. The interval of the fixing portions of the first conductive sheet CS1 and the second conductive sheet CS2 can be reduced, for example, up to the minimum thickness Tmin of the capillary Cp. Accordingly, the plurality of conductive sheets CS can be formed in a narrow region, the magnitude of a force required for bonding each of the conductive sheets CS can be reduced. Damage to the chip can be reduced such that the reliability of the semiconductor device can be improved.

Hereinabove, the embodiments are described with reference to the specific examples. However, the embodiments are not limited to these specific examples. That is, design changes can be made for the specific examples by those skilled in the art and are provided in the range of the embodiments as long as they have the characteristics of the embodiments. The elements, the arrangement of the elements, the materials, the conditions, the shapes, the sizes, and the like in each of the above- described specific examples are not limited to the examples and can be appropriately changed.

In addition, the elements in the above-described embodiments can be combined as long as these combinations are technically possible, and the combinations are provided in the range of the embodiments as long as they have the characteristics of the embodiments. In addition, those skilled in the art can conceive various changes and modifications from the concepts of the embodiments, and it is understood that these changes and modifications belong to the range of the embodiments.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a substrate;
a first electrode provided on the substrate;
a second electrode provided on the substrate distant from the first electrode; and
a conductive sheet connecting the first electrode and the second electrode,
wherein the conductive sheet includes
a first fixing portion connected to the first electrode,
a second fixing portion connected to the second electrode, and
a wiring portion positioned between the first fixing portion and the second fixing portion, having a length in a first direction from the substrate toward the first electrode that is longer than a length of the first fixing portion in the first direction, and having a convex shape with its central part is curving away from the second fixing portion at a first end that is connected to the first fixing portion.

2. The semiconductor device according to claim 1,
wherein the first electrode and the second electrode are distant from each other in a second direction in a first plane intersecting the first direction that is extending from the substrate toward the first electrode, and
a plurality of the conductive sheets extend in the second direction and are located in a third direction intersecting the second direction in the first plane.

3. The semiconductor device according to claim 2,
wherein the wiring portion has a length in the first direction that is longer than a length of the second fixing portion in the first direction and has a concave shape with its central part is curving toward the first fixing portion at a second end that is connected to the second fixing portion.

4. The semiconductor device according to claim 2,
wherein the first end of the wiring portion has an arc shape, and a center of curvature of the first end is positioned in a direction opposite to a direction from the wiring portion to the first fixing portion, relative to the first end.

5. The semiconductor device according to claim 2,
wherein a length Lb1 of the first fixing portion in the second direction and an interval Spx between the conductive sheets located in the third direction satisfy Spx≥Lb1/5.

6. The semiconductor device according to claim 2, further comprising an end portion that is continuous to the first fixing portion, is formed in a direction opposite to the wiring portion with respect to the first fixing portion, and has a length in the first direction that is longer than a length of the first fixing portion in the first direction.

7. The semiconductor device according to claim 6, wherein the end portion has a concave shape with its central part is curving away from the second fixing portion at a third end that is connected to the first fixing portion.

8. The semiconductor device according to claim 1,
wherein the first electrode and the second electrode are distant from each other in a second direction in a first plane intersecting the first direction,
the conductive sheet includes a first conductive sheet and a second conductive sheet extending in the second direction, and
the first fixing portion of the first conductive sheet and the first fixing portion of the second conductive sheet are provided distant from each other in the second direction.

9. The semiconductor device according to claim 1,
wherein the first electrode and the second electrode are source electrodes that are provided on an upper surface of each of a plurality of transistors,
each of the plurality of transistors includes a gate electrode that is provided on the upper surface of the transistor distant from the source electrode and a drain electrode that is provided on a lower surface of the transistor, and
the gate electrodes are connected to each other.

10. A semiconductor device comprising:
a substrate;
a first electrode provided on the substrate;
a second electrode provided on the substrate distant from the first electrode; and
a conductive sheet connecting the first electrode and the second electrode,
wherein the conductive sheet includes
a first fixing portion connected to the first electrode,
a second fixing portion connected to the second electrode, and
a wiring portion positioned between the first fixing portion and the second fixing portion, having a length in a first direction from the substrate toward the first electrode that is longer than a length of the first fixing portion in the first direction, and having a convex shape in a direction from the wiring portion toward the first fixing portion at a first end that is connected to the first fixing portion.

11. The semiconductor device according to claim 10,
wherein the wiring portion has a length in the first direction that is longer than a length of the second fixing portion in the first direction and has a concave shape in a direction from the second fixing portion toward the wiring portion at a second end that is connected to the second fixing portion.

12. The semiconductor device according to claim 10,
wherein the first end of the wiring portion has an arc shape, and a center of curvature of the first end is positioned in a direction opposite to a direction from the wiring portion to the first fixing portion, relative to the first end.

13. The semiconductor device according to claim 10,
wherein a length Lb1 of the first fixing portion in the second direction and an interval Spx between the conductive sheets located in the third direction satisfy Spx≥Lb1/5.

14. A method of manufacturing a semiconductor device having a first electrode and a second electrode using manufacturing machine having a capillary comprising:
a step of moving the capillary where a hole having an arc-shaped portion is filled with a sheet-like conductive sheet toward the first electrode and connecting the conductive sheet and the first electrode to each other to form a first fixing portion;
a step of moving the capillary toward the second electrode to form a wiring portion;
a step of connecting the conductive sheet and the second electrode to each other to form a second fixing portion; and
a step of cutting off the conductive sheet.

15. The method of manufacturing a semiconductor device according to claim 14,
wherein the step of connecting the conductive sheet and the first electrode is to connect the conductive sheet and the first electrode by pressing the conductive sheet in a direction of the first electrode using a half or less of a tip of the capillary.

16. The method of manufacturing a semiconductor device according to claim 15,
wherein the pressing the conductive sheet is to press using the tip of the capillary against a part of the conductive sheet other than a tip of the conductive sheet.

17. The method of manufacturing a semiconductor device according to claim 15, further comprising, when pressing the conductive sheet by the capillary:
a step of applying ultrasonic vibrations to the conductive sheet and the first electrode from the capillary.

18. The method of manufacturing a semiconductor device according to claim 14, further comprising, after the step of cutting off the conductive sheet:
a step of moving the capillary to a region above the first electrode and connecting the conductive sheet and the first electrode to each other to form a third fixing portion; and
a step of lowering the capillary toward the second electrode to form a fourth fixing portion,
wherein the first fixing portion and the third fixing portion are distant from each other in a direction intersecting a direction in which the conductive sheet extends, and
a distance between the first fixing portion and the third fixing portion in the direction intersecting the direction in which the conductive sheet extends is more than or equal to a minimum value of a difference between a radius of an external shape of the capillary and a radius of the hole in a plane parallel to the first electrode.

19. The method of manufacturing a semiconductor device according to claim 14, further comprising, after the step of cutting off the conductive sheet:
a step of moving the capillary to a region above the first electrode and connecting the conductive sheet and the first electrode to each other to form a third fixing portion; and
a step of lowering the capillary toward the second electrode to form a fourth fixing portion,
wherein the first fixing portion and the third fixing portion are distant from each other in a direction in which the conductive sheet extends, and
a distance between the first fixing portion and the third fixing portion in the direction in which the conductive sheet extends is more than or equal to a length obtained by adding a minimum value of a difference between a radius of an external shape of the capillary and a radius of the hole in a plane parallel to the first electrode to a diameter of the hole.
